(19) United States
(12) Patent Application Publication
(10) Pub. No.: US 2005/0156511 A1
(43) Pub. Date: Jul. 21, 2005

(54) Device and method for emitting output light using group IIB element selenide-based phosphor material and/or thiogallate-based phosphor material

(76) Inventors: Janet Bee Yin Chua, Perak (MY); Kee Yean Ng, Penang (MY); Azlida Ahmad, Penang (MY)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/920,496

(22) Filed: Aug. 17, 2004

Related U.S. Application Data
(63) Continuation-in-part of application No. 10/761,763, filed on Jan. 21, 2004.

(51) Int. Cl. H01L 33/00

(52) U.S. Cl. 313/501

(57) ABSTRACT

A device and method for emitting output light utilizes Group IIB element Selenide-based phosphor material and/or Thiogallate-based phosphor material to convert at least some of the original light emitted from a light source of the device to longer wavelength light to change the optical spectrum of the output light. Thus, the device and method can be used to produce white color light.

### REFERENCE TO RELATED APPLICATIONS

This application is a continuation-in-part of application Ser. No. 10/761,763, filed Jan. 21, 2004, for which priority is claimed. The entire prior application is incorporated herein by reference.

### BACKGROUND OF THE INVENTION

Conventional light sources, such as incandescent, halogen and fluorescent lamps, have not been significantly improved in the past twenty years. However, light emitting diode (“LEDs”) have been improved to a point with respect to operating efficiency where LEDs are now replacing the conventional light sources in traditional monochrome lighting applications, such as traffic signal lights and automotive taillights. This is due in part to the fact that LEDs have many advantages over conventional light sources. These advantages include longer operating life, lower power consumption, and smaller size.

LEDs are typically monochromatic semiconductor light sources, and are currently available in various colors from UV-blue to green, yellow and red. Due to the narrow-band emission characteristics, monochromatic LEDs cannot be directly used for “white” light applications. Rather, the output light of a monochromatic LED must be mixed with other light of one or more different wavelengths to produce white light. Two common approaches for producing white light using monochromatic LEDs include (1) packaging individual red, green and blue LEDs together so that light emitted from these LEDs are combined to produce white light and (2) introducing fluorescent material into a UV, blue or green LED so that some of the original light emitted by the semiconductor die of the LED is converted into longer wavelength light and combined with the original UV, blue or green light to produce white light.

Between these two approaches for producing white light using monochromatic LEDs, the second approach is generally preferred over the first approach. In contrast to the second approach, the first approach requires a more complex driving circuitry since the red, green and blue LEDs include semiconductor dies that have different operating voltages requirements. In addition to having different operating voltage requirements, the red, green and blue LEDs degrade differently over their operating lifetime, which makes color control over an extended period difficult using the first approach. Moreover, since only a single type of monochromatic LED is needed for the second approach, a more compact device can be made using the second approach that is simpler in construction and lower in manufacturing cost. Furthermore, the second approach may result in broader light emission, which would translate into white output light having higher color-rendering characteristics.

A concern with the second approach for producing white light is that the fluorescent material currently used to convert the original UV, blue or green light results in LEDs having less than desirable luminance efficiency and/or light output stability over time.

In view of this concern, there is a need for an LED and method for emitting white output light using a fluorescent phosphor material with high luminance efficiency and good light output stability.

### SUMMARY OF THE INVENTION

A device and method for emitting output light utilizes Group IIB element Selenide-based phosphor material and/or Thiogallate-based phosphor material to convert at least some of the original light emitted from a light source of the device to longer wavelength light to change the optical spectrum of the output light. Thus, the device and method can be used to produce white color light.

A device for emitting output light in accordance with an embodiment of the invention includes a light source that emits first light of a first peak wavelength and a wavelength-shifting region optically coupled to the light source to receive the first light. The wavelength-shifting region includes Group IIB element Selenide-based phosphor material having a property to convert some of the first light to second light of a second peak wavelength. The wavelength-shifting region further includes Thiogallate-based phosphor material having a property to convert some of the first light to third light of a third peak wavelength. The second light and the third light are components of the output light.

A device for emitting output light in accordance with another embodiment of the invention includes a light source that emits first light of a first peak wavelength and a wavelength-shifting region optically coupled to the light source to receive the first light. The wavelength-shifting region includes Thiogallate-based phosphor material having a structure defined by MNₓS_{y}, where M is an element selected from a group consisting of Barium, Calcium, Strontium and Magnesium, N is an element selected from a group consisting of Aluminum, Gallium and Indium, and x and y are numbers. The Thiogallate-based phosphor material has a property to convert at least some of the first light to second light of a second peak wavelength. The second light is a component of the output light.

A method for emitting output light in accordance with an embodiment of the invention includes generating first light, receiving the first light, including converting some of the first light to second light of a second peak wavelength using Group IIB element Selenide-based phosphor material and converting some of the first light to third light of a third peak wavelength using Thiogallate-based phosphor material, and emitting the second light and the third light as components of the output light.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of a white phosphor-converted LED in accordance with an embodiment of the invention.

FIGS. 2A, 2B and 2C are diagrams of white phosphor-converted LEDs with alternative lamp configurations in accordance with an embodiment of the invention.

FIGS. 3A, 3B, 3C and 3D are diagrams of white phosphor-converted LEDs with a leadframe having a reflector cup in accordance with an alternative embodiment of the invention.

FIG. 4 shows the optical spectrum of a white phosphor-converted LED with a blue LED die in accordance with an embodiment of the invention.

FIG. 5 is a plot of luminance (lv) degradation over time for a white phosphor-converted LED in accordance with an embodiment of the invention.

FIG. 6 is a flow diagram of a method for emitting output light in accordance with an embodiment of the invention.

### DETAILED DESCRIPTION

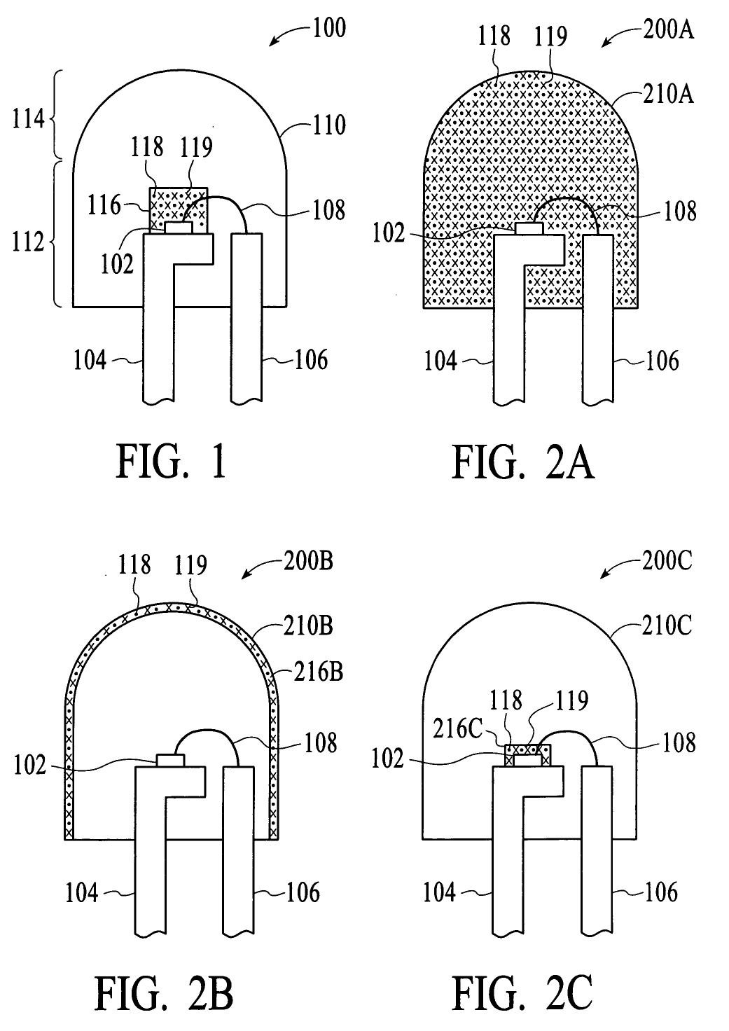

With reference to FIG. 1, a white phosphor-converted light emitting diode (LED) 100 in accordance with an embodiment of the invention is shown. The LED 100 is designed to produce “white” color output light with high luminance efficiency and good light output stability. The white output light is produced by converting some of the original light generated by the LED 100 into longer wavelength light using Group IIB element Selenide-based phosphor material and Thiogallate-based phosphor material.

As shown in FIG. 1, the white phosphor-converted LED 100 is a leadframe-mounted LED. The LED 100 includes an LED die 102, leadframes 104 and 106, a wire 108 and a lamp 110. The LED die 102 is a semiconductor chip that generates light of a particular peak wavelength. Thus, the LED die 102 is a light source for the LED 100. In an exemplary embodiment, the LED die 102 is designed to generate light having a peak wavelength in the blue wavelength range of the visible spectrum, which is approximately 420 mm to 490 nm. The LED die 102 is situated on the leadframe 104 and is electrically connected to the other leadframe 106 via the wire 108. The leadframes 104 and 106 provide the electrical power needed to drive the LED die 102. The LED die 102 is encapsulated in the lamp 110, which is a medium for the propagation of light from the LED die 102. The lamp 110 includes a main section 112 and an output section 114. In this embodiment, the output section 114 of the lamp 110 is dome-shaped to function as a lens. Thus, the light emitted from the LED 100 as output light is focused by the dome-shaped output section 114 of the lamp 110. However, in other embodiments, the output section 114 of the lamp 100 may be horizontally planar.

The lamp 110 of the white phosphor-converted LED 100 is made of a transparent substance, which can be any transparent material such as clear epoxy, so that light from the LED die 102 can travel through the lamp and be emitted out of the output section 114 of the lamp. In this embodiment, the lamp 110 includes a wavelength-shifting region 116, which is also a medium for propagating light, made of a mixture of the transparent substance and two types of fluorescent phosphor materials based on Group IIB element Selenide 118 and Thiogallate 119. The Group IIB element Selenide-based phosphor material 118 and the Thiogallate-based phosphor material 119 are used to convert some of the original light emitted by the LED die 102 to lower energy (longer wavelength) light. The Group IIB element Selenide-based phosphor material 118 absorbs some of the original light of a first peak wavelength from the LED die 102, which excites the atoms of the Group IIB element Selenide-based phosphor material, and emits longer wavelength light of a second peak wavelength. In the exemplary embodiment, the Group IIB element Selenide-based phosphor material 118 has a property to convert some of the original light from the LED die 102 into light of a longer peak wavelength in the red wavelength range of the visible spectrum, which is approximately 620 nm to 800 nm. Similarly, the Thiogallate-based phosphor material 119 absorbs some of the original light from the LED die 102, which excites the atoms of the Thiogallate-based phosphor material, and emits longer wavelength light of a third peak wavelength. In the exemplary embodiment, the Thiogallate-based phosphor material 119 has a property to convert some of the original light from the LED die 102 into light of a longer peak wavelength in the green wavelength range of the visible spectrum, which is approximately 490 nm to 575 nm. The second and third peak wavelengths of the converted light are partly defined by the peak wavelength of the original light and the Group IIB element Selenide-based phosphor material 118 and the Thiogallate-based phosphor material 1119. The unabsorbed original light from the LED die 102 and the converted light are combined to produce “white” color light, which is emitted from the light output section 114 of the lamp 110 as output light of the LED 100.

In one embodiment, the Group IIB element Selenide-based phosphor material 118 included in the wavelength-shifting region 116 of the lamp 110 is phosphor made of Zinc Selenide (ZnSe) activated by one or more suitable dopants, such as Copper (Cu), Chlorine (Cl), Fluorine (F), Bromine (Br) and Silver (Ag) and rare earth elements. In an exemplary embodiment, the Group IIB element Selenide-based phosphor material 118 is phosphor made of ZnSe activated by Cu, i.e., ZnSe:Cu. Unlike conventional fluorescent phosphor materials that are used for producing white color light using LEDs, such as those based on alumina, oxide, sulfide, phosphate and halophosphate, ZnSe:Cu phosphor is highly efficient with respect to the wavelength-shifting conversion of light emitted from an LED die. This is due to the fact that most conventional fluorescent phosphor materials have a large bandgap, which prevents the phosphor materials from efficiently absorbing and converting light, e.g., blue light, to longer wavelength light. In contrast, the ZnSe:Cu phosphor has a lower bandgap, which equates to a higher efficiency with respect to wavelength-shifting conversion via fluorescence.

The Thiogallate-based phosphor material 119 included in the wavelength-shifting region 116 of the lamp 110 may be a metal-Thiogallate-based phosphor material activated by one or more suitable dopants, such as rare earth elements. The metal-Thiogallate-based phosphor material may have a structure defined by MNXSY, where M is a Group IIA element, such as Barium (Ba), Calcium (Ca), Strontium (Sr) and Magnesium (Mg), N is a Group IIIA element, such as Aluminum (Al), Gallium (Ga) and Indium (In), and x and y are numbers, for example, x is equal to 2 and y is equal to 4, or x is equal to 4 and y is equal to 7. In one embodiment, the Thiogallate-based phosphor material 119 is a Group IIA element Gallium Sulfide-based phosphor material, where Group IIA element can be Ca, Sr and/or Ba. As an example, the Thiogallate-based phosphor material 119 may be phosphor made of Barium Gallium Sulfide activated by one or more suitable dopants, such as rare earth elements. Preferably, the Thiogallate-based phosphor material 119 is phosphor made of Barium Gallium Sulfide activated by Europium (Eu), i.e., BaGa₄S₇:Eu.

The preferred ZnSe:Cu phosphor can be synthesized by various techniques. One technique involves dry-milling a predefined amount of undoped ZnSe material into fine powders or crystals, which may be less than 5 μm. A small amount of Cu dopant is then added to a solution from the alcohol family, such as methanol, and ball-milled with the undoped ZnSe powders. The amount of Cu dopant added to the solution can be anywhere between a minimal amount to approximately six percent of the total weight of ZnSe material and Cu dopant. The doped material is then oven-dried at around one hundred degrees Celsius (100° C.), and the resulting cake is dry-milled again to produce small particles. The milled material is loaded into a crucible, such as a quartz crucible, and sintered in an inert atmosphere at around one thousand degrees Celsius (1,000° C.) for one to two hours. The sintered materials can then be sieved, if necessary, to produce ZnSe:Cu phosphor powders with desired particle size distribution, which may be in the micron range.

The ZnSe:Cu phosphor powders may be further processed to produce phosphor particles with a silica coating. Silica coating on phosphor particles reduces clustering or agglomeration of phosphor particles when the phosphor particles are mixed with a transparent substance to form a wavelength-shifting region in an LED, such as the wavelength-shifting region 116 of the lamp 110. Clustering or agglomeration of phosphor particles can result in an LED that produces output light having a non-uniform color distribution.

In order to apply a silica coating to the ZnSe:Cu phosphor particles, the sieved materials are subjected to an annealing process to anneal the phosphor particles and to remove contaminants. Next, the phosphor particles are mixed with silica powders, and then the mixture is heated in a furnace at approximately 200 degrees Celsius. The applied heat forms a thin silica coating on the phosphor particles. The amount of silica on the phosphor particles is approximately 1% with respect to the phosphor particles. The resulting ZnSe:Cu phosphor particles with silica coating may have a particle size of less than or equal to thirty (30) microns.

The preferred BaGa₄S₇:Eu phosphor can also be synthesized by various techniques. One technique involves using BaS and Ga₂S₃ as precursors. The precursors are ball-milled in a solution from the alcohol family, such as methanol, along with a small amount of Eu dopant, fluxes (Cl and F) and excess Sulfur. The amount of Eu dopant added to the solution can be anywhere between a minimal amount to approximately six percent of the total weight of all ingredients. The doped material is then dried and subsequently milled to produce fine particles. The milled particles are then loaded into a crucible, such as a quartz crucible, and sintered in an inert atmosphere at around eight hundred degrees Celsius (800° C.) for one to two hours. The sintered materials can then be sieved, if necessary, to produce BaGa₄S₇:Eu phosphor powders with desired particle size distribution, which may be in the micron range.

Similar to the ZnSe:Cu phosphor powders, the BaGa₄S₇:Eu phosphor powders may be further processed to produce phosphor particles with a silica coating. The resulting BaGa₄S₇:Eu phosphor particles with silica coating may have a particle size of less than or equal to forty (40) microns.

Following the completion of the ZnSe:Cu and BaGa₄S₇:Eu synthesis processes, the ZnSe:Cu and BaGa₄S₇:Eu phosphor powders can be mixed with the same transparent substance of the lamp 110, e.g., epoxy, and deposited around the LED die 102 to form the wavelength-shifting region 116 of the lamp. The ratio between the two different types of phosphor powders can be adjusted to produce different color characteristics for the white phosphor-converted LED 100. As an example, the ratio between the ZnSe:Cu phosphor powers and the BaGa₄S₇:Eu phosphor powders may be 1:5, respectively. The remaining part of the lamp 110 can be formed by depositing the transparent substance without the ZnSe:Cu and BaGa₄S₇:Eu phosphor powders to produce the LED 100. Although the wavelength-shifting region 116 of the lamp 110 is shown in FIG. 1 as being rectangular in shape, the wavelength-shifting region may be configured in other shapes, such as a hemisphere. Furthermore, in other embodiments, the wavelength-shifting region 116 may not be physically coupled to the LED die 102. Thus, in these embodiments, the wavelength-shifting region 116 may be positioned elsewhere within the lamp 110.

In FIGS. 2A, 2B and 2C, white phosphor-converted LEDs 200A, 200B and 200C with alternative lamp configurations in accordance with an embodiment of the invention are shown. The white phosphor-converted LED 200A of FIG. 2A includes a lamp 210A in which the entire lamp is a wavelength-shifting region. Thus, in this configuration, the entire lamp 210A is made of the mixture of the transparent substance and the Group IIB element Selenide-based and Thiogallate-based phosphor materials 118 and 119. The white phosphor-converted LED 200B of FIG. 2B includes a lamp 210B in which a wavelength-shifting region 216B is located at the outer surface of the lamp. Thus, in this configuration, the region of the lamp 210B without the Group IIB element Selenide-based and Thiogallate-based phosphor materials 118 and 119 is first formed over the LED die 102 and then the mixture of the transparent substance and the phosphor materials is deposited over this region to form the wavelength-shifting region 216B of the lamp. The white phosphor-converted LED 200C of FIG. 2C includes a lamp 210C in which a wavelength-shifting region 216C is a thin layer of the mixture of the transparent substance and the Group IIB element Selenide-based and Thiogallate-based phosphor materials 118 and 119 coated over the LED die 102. Thus, in this configuration, the LED die 102 is first coated or covered with the mixture of the transparent substance and the Group IIB element Selenide-based and Thiogallate-based phosphor materials 118 and 119 to form the wavelength-shifting region 216C and then the remaining part of the lamp 210C can be formed by depositing the transparent substance without the phosphor materials over the wavelength-shifting region. As an example, the thickness of the wavelength-shifting region 216C of the LED 200C can be between ten (10) and sixty (60) microns, depending on the color of the light generated by the LED die 102.

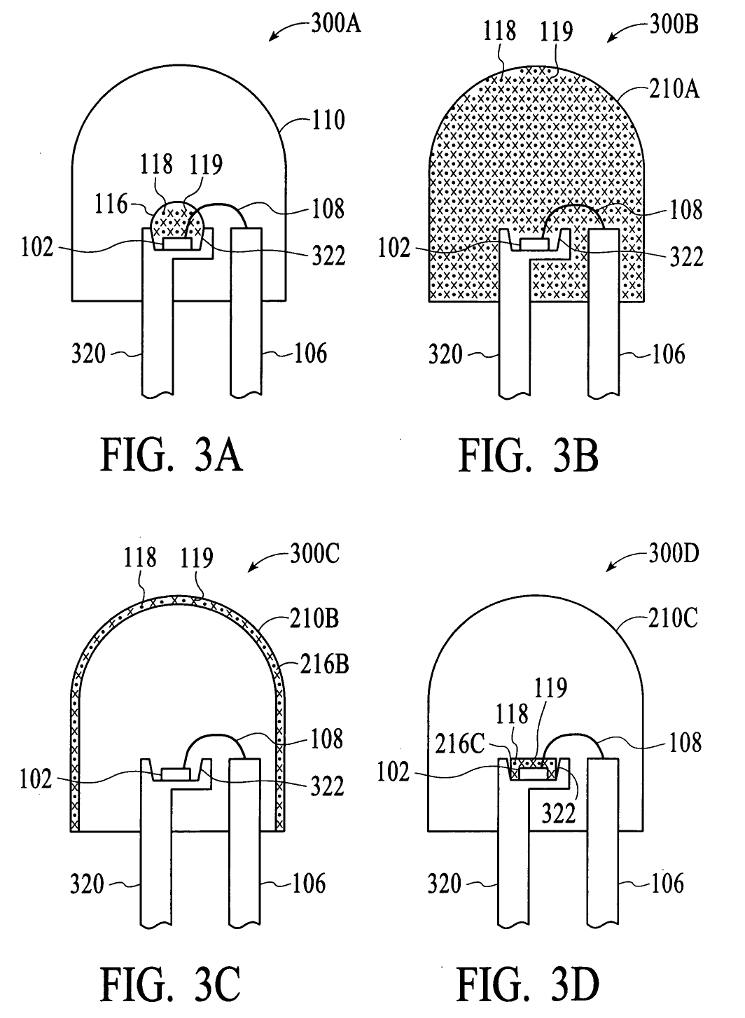

In an alternative embodiment, the leadframe of a white phosphor-converted LED on which the LED die is positioned may include a reflector cup, as illustrated in FIGS. 3A, 3B, 3C and 3D. FIGS. 3A-3D show white phosphor-converted LEDs 300A, 300B, 300C and 300D with different lamp configurations that include a leadframe 320 having a reflector cup 322. The reflector cup 322 provides a depressed region for the LED die 102 to be positioned so that some of the light generated by the LED die is reflected away from the leadframe 320 to be emitted from the respective LED as useful output light.

The different lamp configurations described above can be applied other types of LEDs, such as surface-mounted LEDs, to produce other types of white phosphor-converted LEDs with Group IIB element Selenide-based and Thiogallate-based phosphor materials in accordance with the invention. In addition, these different lamp configurations may be applied to other types of light emitting devices, such as semiconductor lasing devices, to produce other types of light emitting devices in accordance with the invention. In these light emitting devices, the light source can be any light source other than an LED die, such as a laser diode.

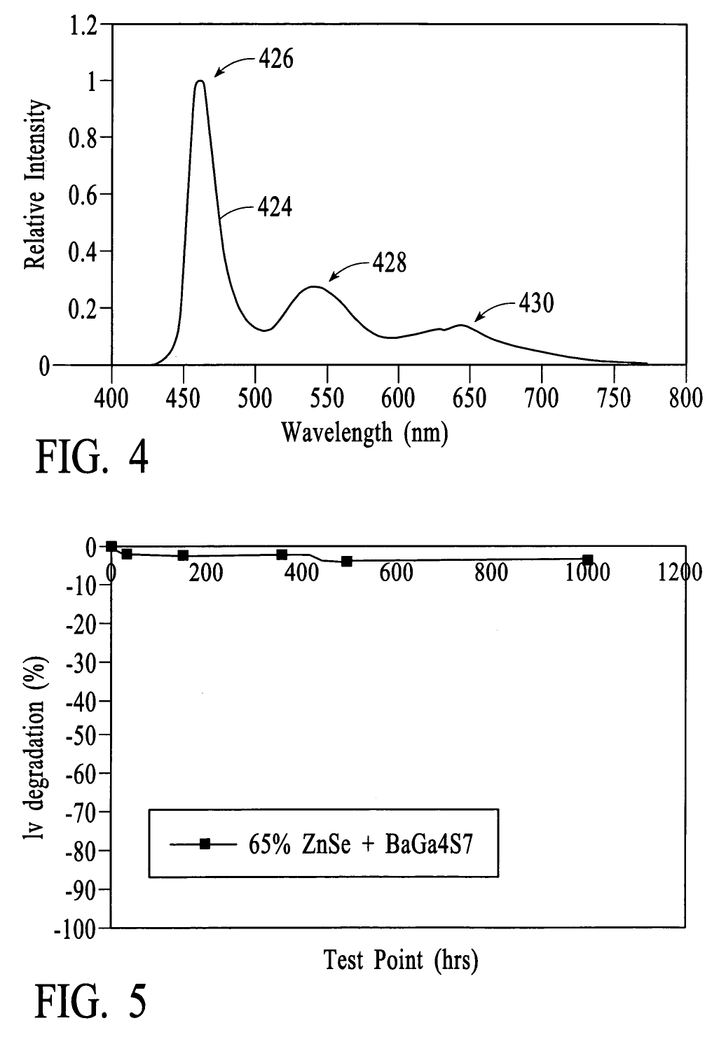

Turning now to FIG. 4, the optical spectrum 424 of a white phosphor-converted LED with a blue (440-480 nm) LED die in accordance with an embodiment of the invention is shown. The wavelength-shifting region for this LED was formed with sixty-five percent (65%) of ZnSe:Cu and BaGa₄S₇:Eu phosphors relative to epoxy. The percentage amount or loading content of ZnSe:Cu and BaGa₄S₇:Eu phosphors included in the wavelength-shifting region of the LED can be varied according to phosphor efficiency. As the phosphor efficiency is increased, e.g., by changing the amount of dopant(s), the loading content of the ZnSe:Cu and BaGa₄S₇:Eu phosphors may be reduced. The optical spectrum 424 includes a first peak wavelength 426 at around 460 nm, which corresponds to the peak wavelength of the light emitted from the blue LED die. The optical spectrum 424 also includes a second peak wavelength 428 at around 540 nm, which is the peak wavelength of the light converted by the BaGa₄S₇:Eu phosphor in the wavelength-shifting region of the LED, and a third peak wavelength 430 at around 645 nm, which is the peak wavelength of the light converted by the ZnSe:Cu phosphor in the wavelength-shifting regions of the LED.

FIG. 5 is a plot of luminance (lv) degradation over time for a white phosphor-converted LED having a wavelength-shifting region with sixty-five percent (65%) of ZnSe:Cu and BaGa₄S₇:Eu phosphors relative to epoxy in accordance with an embodiment of the invention. As illustrated by the plot of FIG. 5, the luminance properties of the white phosphor-converted LED experience little change over an extended period of time while being exposed to high intensity light, i.e., the light emitted from the semiconductor die of the LED. Thus, the ZnSe:Cu and BaGa₄S₇:Eu phosphors used in the LED have good resistance against light. This resistance to light is not limited to the light emitted from the semiconductor die of an LED, but also any external light, such as sunlight including ultraviolet light. Thus, LEDs in accordance with the invention are suitable for outdoor use, and can provide stable luminance over time with minimal color shift. In addition, these LEDs can be used in applications that require high response speeds since the duration of afterglow for the ZnSe:Cu and BaGa₄S₇:Eu phosphors is short.

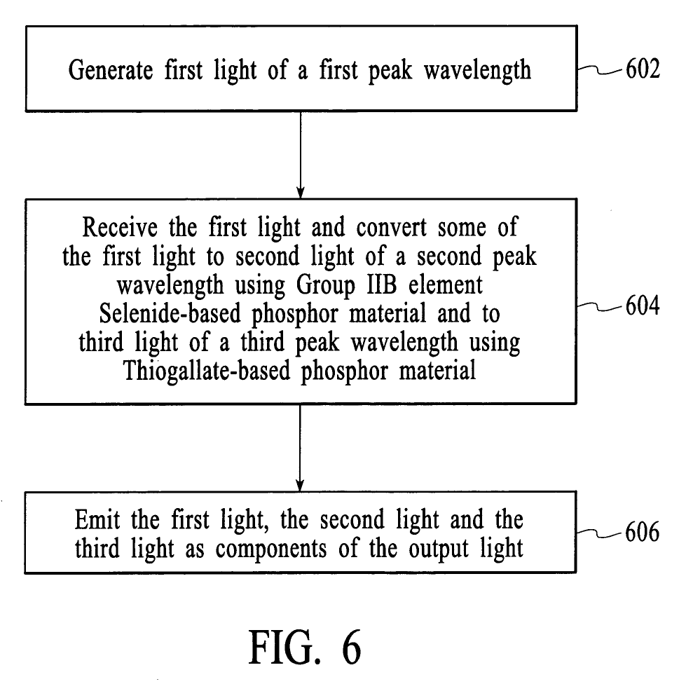

A method for producing white output light in accordance with an embodiment of the invention is described with reference to FIG. 6. At block 602, first light of a first peak wavelength is generated. The first light may be generated by an LED die, such as a UV or blue LED die. Next, at block 604, the first light is received and some of the first light is converted to second light of a second peak wavelength using Group IIB element Selenide-based phosphor material. In addition, at block 604, some of the first light is converted to third light of a third peak wavelength using Thiogallate-based phosphor material. Next, at block 606, the first light, the second light and the third light are emitted as components of the output light.

Although specific embodiments of the invention have been described and illustrated, the invention is not to be limited to the specific forms or arrangements of parts so described and illustrated. Furthermore, the invention is not limited to devices and methods for producing white output lights. The invention also includes devices and methods for producing other types of output light. As an example, the Group IIB element Selenide-based phosphor material and/or the Thiogallate-based phosphor material in accordance with the invention may be used in a light emitting device where virtually all of the original light generated by a light source is converted to light of different wavelength, in which case the color of the output light may not be white. The scope of the invention is to be defined by the claims appended hereto and their equivalents.

1. A device for emitting output light, said device comprising:
a light source that emits first light of a first peak wavelength; and
a wavelength-shifting region optically coupled to said light source to receive said first light, said wavelength-shifting region including Group IIB element Selenide-based phosphor material having a property to convert some of said first light to second light of a second peak wavelength, said wavelength-shifting region further including Thiogallate-based phosphor material having a property to convert some of said first light to third light of a third peak wavelength, said second light and said third light being components of said output light.

2. The device of claim 1 wherein at least one of said Group IIB element Selenide-based phosphor material and said Thiogallate-based phosphor material is doped with at least one rare earth element.

3. The device of claim 1 wherein said Group IIB element Selenide-based phosphor material of said wavelength-shifting region includes one of Zinc Selenide and Cadmium Selenide.

4. The device of claim 3 wherein said Group IIB element Selenide-based phosphor material includes said Zinc Selenide activated by at least one element selected from a group consisting of Copper, Chlorine, Fluorine, Bromine and Silver.

5. The device of claim 1 wherein said Thiogallate-based phosphor material has a structure defined by MNₓS_{y} where M is an element selected from a group consisting of Barium, Calcium, Strontium and Magnesium, N is an element selected from a group consisting of Aluminum, Gallium and Indium, and x and y are numbers.

6. The device of claim 5 wherein said Thiogallate-based phosphor material has a structure defined by one of MN₂S₄ and MN₄S₇.

7. The device of claim 1 wherein said Thiogallate-based phosphor material includes Barium Gallium Sulfide activated by a rare metal element.

8. The device of claim 7 wherein said Thiogallate-based phosphor material includes said Barium Gallium Sulfide activated by Europium as defined by the formula: BaGa₄S₇:Eu.

9. The device of claim 1 wherein at least one of said Group IIB element Selenide-based phosphor material and said Thiogallate-based phosphor material includes phosphor particles having a silica coating.

10. The device of claim 1 wherein said Group IIB element Selenide-based phosphor material includes phosphor particles having particle size of less than or equal to 30 microns.

11. The device of claim 1 wherein said Thiogallate-based phosphor material includes phosphor particles having particle size of less than or equal to 40 microns.

12. A method of emitting output light, said method comprising:
generating first light of a first peak wavelength;
receiving said first light, including converting some of said first light to second light of a second peak wavelength using Group IIB element Selenide-based phosphor material and converting some of said first light to third light of a third peak wavelength using Thiogallate-based phosphor material; and
emitting said second light and said third light as components of said output light.

13. The method of claim 12 wherein at least one of said Group IIB element Selenide-based phosphor material and said Thiogallate-based phosphor material is doped with at least one rare earth element.

14. The method of claim 12 wherein said Group IIB element Selenide-based phosphor material includes one of Zinc Selenide and Cadmium Selenide.

15. The method of claim 12 wherein said Thiogallate-based phosphor material has a structure defined by MNₓS_{y}, where M is an element selected from a group consisting of Barium, Calcium, Strontium and Magnesium, N is an element selected from a group consisting of Aluminum, Gallium and Indium, and x and y are numbers.

16. The method of claim 15 wherein said Thiogallate-based phosphor material has a structure defined by one of MN₂S₄ and MN₄S₇.

17. The method of claim 12 wherein said Thiogallate-based phosphor material includes Barium Gallium Sulfide activated by a rare metal element.

18. The method of claim 12 wherein at least one of said Group IIB element Selenide-based phosphor material and said Thiogallate-based phosphor material includes phosphor particles having a silica coating.

19. The method of claim 12 wherein said Group IIB element Selenide-based phosphor material includes phosphor particles having particle size of less than or equal to 30 microns, and wherein said Thiogallate-based phosphor material includes phosphor particles having particle size of less than or equal to 40 microns.

20. A device for emitting output light, said device comprising:
a light source that emits first light of a first peak wavelength; and
a wavelength-shifting region optically coupled to said light source to receive said first light, said wavelength-shifting region including Thiogallate-based phosphor material having a structure defined by MNₓS_{y}, where M is an element selected from a group consisting of Barium, Calcium, Strontium and Magnesium, N is an element selected from a group consisting of Aluminum, Gallium and Indium, and x and y are numbers, said Thiogallate-based phosphor material having a property to at least convert some of said first light to second light of a second peak wavelength, said second light being a component of said output light.

21. The device of claim 20 wherein said wavelength-shifting region includes Group IIB element Selenide-based phosphor material having a property to convert some of said first light to third light of a third peak wavelength, said third light being a component of said output light.

22. The device of claim 21 wherein one of said Thiogallate-based phosphor material and said Group IIB element Selenide-based phosphor material is doped with at least one rare earth element.

23. The device of claim 20 wherein at least one of said Group IIB element Selenide-based phosphor material and said Thiogallate-based phosphor material includes phosphor particles having a silica coating.

24. The device of claim 20 wherein said Thiogallate-based phosphor material has a structure defined by MN₂S₄.

25. The device of claim 20 wherein said Thiogallate-based phosphor material has a structure defined by MN₄S₇.

26. The method of claim 20 wherein said Thiogallate-based phosphor material includes phosphor particles having a silica coating.
